(19) United States
(12) Patent Application Publication
(10) Pub. No.: US 2025/0008807 A1
(43) Pub. Date: Jan. 2, 2025

(54) Color Filter Substrate and Display Device

(71) Applicant: LG Display Co., Ltd., Seoul (KR)

(72) Inventors: Jaeyeong Kim, Paju-si (KR); YounSik Kim, Paju-si (KR)

(21) Appl. No.: 18/753,981

(22) Filed: Jun. 25, 2024

(30) Foreign Application Priority Data
Jun. 28, 2023 (KR) 10-2023-0083714

(51) Int. Cl. H10K 59/38; H10K 59/65; H10K 59/80

(52) U.S. Cl. CPC H10K 59/38; H10K 59/65; H10K 59/8792

(57) ABSTRACT

A color filter substrate and a display device are disclosed. A color filter substrate and a display device implement an infrared filter selectively transmitting infrared light by having a color pattern stack by stacking color patterns having the same or substantially same configuration as the color filter layer.

### CROSS-REFERENCE TO RELATED APPLICATION

This application claims priority from Republic of Korea Patent Application No. 10-2023-0083714, filed on Jun. 28, 2023, which is hereby incorporated by reference in its entirety.

### BACKGROUND

### Field

Embodiments of the disclosure relate to a color filter substrate and a display device.

### Description of Related Art

The growth of the intelligent society leads to increased demand for various types of display devices. Representative examples of such display devices include liquid crystal devices (LCD) and organic light emitting display devices (OLED).

Recently, as their functions are further diversified, display devices come up with optical sensors, such as iris recognition sensors or proximity sensors, as well as photographing devices for photo and video recording.

The display device may recognize the user's iris using an optical sensor and determine whether the display device is activated by comparing the recognized iris and a stored value. Further, the display device may detect a change in the amount of light around the display device using an optical sensor and adjust the brightness of the display device or deactivate the display device through the detected change.

### SUMMARY

Embodiments of the disclosure may provide a color filter substrate and a display device for implementing an infrared filter that selectively transmits infrared light by having a color pattern stack that stacks color patterns having the same or substantially same configuration as the color filter layer.

Embodiments of the disclosure may provide a color filter substrate and a display device for implementing an infrared filter that reduces external visibility without a separate infrared ink by providing a color pattern stack by stacking color patterns having the same or substantially same configuration as the color filter layer.

Embodiments of the disclosure may provide a color filter substrate and a display device for process optimization with a simplified manufacturing process by forming a color pattern stack by simultaneously stacking color patterns having the same or substantially same configuration as the color filter layer.

Embodiments of the disclosure may provide a color filter substrate and a display device for implementing a uni-material product by forming a color pattern stack by simultaneously stacking color patterns having the same or substantially same configuration as the color filter layer.

In one embodiment, a color filter substrate comprises: a substrate; a color filter layer on the substrate and including a first color filter having a first color, a second color filter having a second color that is different from the first color, and a third color filter having a third color that is different from the first color and the second color, and the color filter layer configured to be positioned in areas respectively corresponding to a plurality of subpixels; a color pattern stack configured to be disposed over a sensor area, the color pattern stack including a first color pattern and a second color pattern on the first color pattern and having a different color from the first color pattern; and a planarization layer on the color filter layer and the color pattern stack.

In one embodiment, a display device comprises: a first substrate including a plurality of subpixels and a sensor area; a color filter layer including a first color filter having a first color, a second color filter having a second color that is different from the first color, and a third color filter having a third color that is different from the first color and the second color, and the color filter layer overlapping the plurality of subpixels; a color pattern stack overlapping the sensor area, the color pattern stack including a first color pattern and a second color pattern on the first color pattern and having a different color from the first color pattern; a planarization layer on the color filter layer and the color pattern stack; a second substrate on the planarization layer; and a sensor module overlapping the sensor area.

In one embodiment, a display device comprises: a substrate including a first area and a second area that is spaced apart from the first area; a plurality of subpixels in the first area without being in the second area; a color filter overlapping the plurality of subpixels in the first area; and a color pattern stack overlapping the second area, the color pattern stack including a first color pattern having a first color and a second color pattern on the first color pattern and having a second color that is different from the first color.

According to embodiments of the disclosure, there may be provided a color filter substrate and a display device for implementing an infrared filter selectively transmitting infrared light by having a color pattern stack by stacking color patterns having the same or substantially same configuration as the color filter layer.

According to embodiments of the disclosure, there may be provided a color filter substrate and a display device for implementing an infrared filter that reduces external visibility without a separate infrared ink by providing a color pattern stack by stacking color patterns having the same or substantially same configuration as the color filter layer.

According to embodiments of the disclosure, there may be provided a color filter substrate and a display device for process optimization with a simplified manufacturing process by forming a color pattern stack by simultaneously stacking color patterns having the same or substantially same configuration as the color filter layer.

According to embodiments of the disclosure, there may be provided a color filter substrate and a display device for implementing a uni-material product by forming a color pattern stack by simultaneously stacking color patterns having the same or substantially same configuration as the color filter layer.

### BRIEF DESCRIPTION OF DRAWINGS

The above and other objects, features, and advantages of the disclosure will be more clearly understood from the following detailed description, taken in conjunction with the accompanying drawings, in which:

FIG. 1 is a view illustrating a system configuration of a display device according to embodiments of the disclosure;

FIG. 2 is an equivalent circuit diagram illustrating a subpixel in a display panel according to embodiments of the disclosure;

FIG. 3 is an equivalent circuit diagram illustrating a subpixel having a 2-gate driving structure in a display panel according to embodiments of the disclosure;

FIG. 4 is another equivalent circuit diagram illustrating a subpixel in a display panel according to embodiments of the disclosure;

FIG. 5 is a view illustrating a color filter substrate according to embodiments of the disclosure;

FIG. 6 is a view illustrating a sensor area in a color filter substrate according to embodiments of the disclosure;

FIG. 7 is a graph illustrating the light transmittance according to color filters in a color filter substrate according to embodiments of the disclosure;

FIGS. 8 and 9 are views illustrating a color filter substrate according to embodiments of the disclosure;

FIGS. 10, 11, 12, and 13 are views illustrating a display device according to embodiments of the disclosure; and

FIG. 14 is a view illustrating a camera area and a sensor area in a display device according to embodiments of the disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted or may be briefly provided when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it is typically interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it may be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

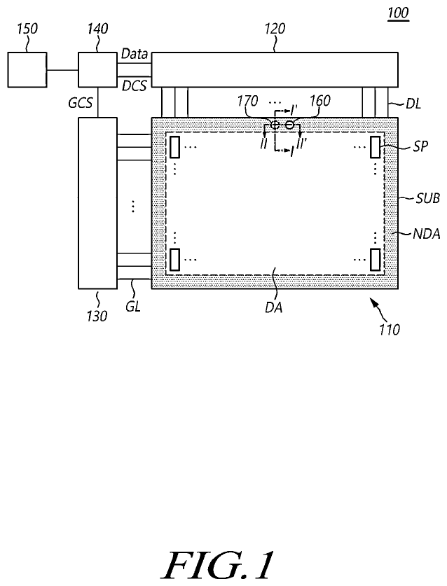

FIG. 1 is a view illustrating a system configuration of a display device 100 according to embodiments of the disclosure.

Referring to FIG. 1, a display device 100 according to embodiments of the disclosure may include a display panel 110 including a plurality of subpixels SP and driving circuits for driving the plurality of subpixels SP included in the display panel 110.

The driving circuits may include a data driving circuit 120 and a gate driving circuit 130. The display device 100 may further include a controller 140 controlling the data driving circuit 120 and the gate driving circuit 130.

The display panel 110 may include a substrate SUB and signal lines, such as a plurality of data lines DL and a plurality of gate lines GL disposed on the substrate SUB. The plurality of data lines DL and the plurality of gate lines GL may be connected to the plurality of subpixels SP.

The display panel 110 may include a display area DA (e.g., a first area) in which images are displayed and a non-display area NDA (e.g., a second area spaced apart from the first area) in which no image is displayed. In the display panel 110, a plurality of subpixels SP for displaying images may be disposed in the display area DA, and the driving circuits 120, 130, and controller 140 may be electrically connected or disposed in the non-display area NDA. Further, pad units for connection of integrated circuits or a printed circuit may be disposed in the non-display area NA.

The data driving circuit 120 is a circuit for driving the plurality of data lines DL, and may supply data signals to the plurality of data lines DL.

The gate driving circuit 130 is a circuit for driving the plurality of gate lines GL, and may supply gate signals to the plurality of gate lines GL.

The controller 140 may supply a data control signal DCS to the data driving circuit 120 to control the operation timing of the data driving circuit 120 and may supply a gate control signal GCS to the gate driving circuit 130 to control the operation timing of the gate driving circuit 130.

The controller 140 may start scanning according to a timing implemented in each frame, convert input image data input from the outside into image data Data suited for the data signal format used in the data driving circuit 120, supply the image data Data to the data driving circuit 120, and control data driving at an appropriate time suited for scanning.

The controller 140 receives, from the outside (e.g., a host system 150), various timing signals including a vertical synchronization signal VSYNC, a horizontal synchronization signal HSYNC, an input data enable signal DE, and a clock signal, along with the input image data.

To control the data driving circuit 120 and the gate driving circuit 130, the controller 140 receives timing signals, such as the vertical synchronization signal VSYNC, horizontal synchronization signal HSYNC, input data enable signal DE, and clock signal CLK, generates various control signals DCS and GCS, and outputs the control signals to the data driving circuit 120 and the gate driving circuit 130.

As an example, to control the gate driving circuit 130, the controller 140 outputs various gate control signals GCS including a gate start pulse GSP, a gate shift clock GSC, and a gate output enable signal (Gate Output Enable, GOE).

To control the data driving circuit 120, the controller 140 outputs various data control

signals DCS including, e.g., a source start pulse SSP, a source sampling clock SSC, and a source output enable signal (Source Output Enable, SOE).

The controller 140 may be implemented as a separate component from the data driving circuit 120, or the controller 140, along with the data driving circuit 120, may be implemented as an integrated circuit.

The data driving circuit 120 receives the image data Data from the controller 140 and supply data voltages to the plurality of data lines DL, thereby driving the plurality of data lines DL. The data driving circuit 120 is also referred to as a ‘source driving circuit.’

The data driving circuit 120 may include one or more source driver integrated circuit SDIC.

Each source driver integrated circuit (SDIC) may include a shift register, a latch circuit, a digital-to-analog converter (DAC), and an output buffer. In some cases, each source driver integrated circuit (SDIC) may further include an analog-digital converter ADC.

For example, each source driver integrated circuit (SDIC) may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110.

The gate driving circuit 130 may output a gate signal of a turn-on level voltage or a gate signal of a turn-off level voltage according to the control of the controller 140. The gate driving circuit 130 may sequentially drive the plurality of gate lines GL by sequentially supplying gate signals of the turn-on level voltage to the plurality of gate lines GL.

The gate driving circuit 130 may be connected with the display panel 110 by TAB method or connected to a bonding pad of the display panel 110 by a COG or COP method or may be connected with the display panel 110 according to a COF method. Alternatively, the gate driving circuit 130 may be formed in a gate in panel (GIP) type, in the non-display area NDA of the display panel 110. The gate driving circuit 130 may be disposed on the substrate SUB or may be connected to the substrate SUB. In other words, the gate driving circuit 130 that is of a GIP type may be disposed in the non-display area NDA of the substrate SUB. The gate driving circuit 130 that is of a chip-on-glass (COG) type or chip-on-film (COF) type may be connected to the substrate SUB.

Meanwhile, at least one of the data driving circuit 120 and the gate driving circuit 130 may be disposed in the display area DA. For example, at least one of the data driving circuit 120 and the gate driving circuit 130 may be disposed not to overlap the subpixels SP or to overlap all or some of the subpixels SP.

When a selected gate line GL is driven by the gate driving circuit 130, the data driving circuit 120 may convert the image data Data received from the controller 140 into an analog data voltage and supply it to the plurality of data lines DL.

The data driving circuit 120 may be connected to one side (e.g., an upper or lower side) of the display panel 110. Depending on the driving scheme or the panel design scheme, data driving circuits 120 may be connected with both the sides (e.g., both the upper and lower sides) of the display panel 110, or two or more of the four sides of the display panel 110.

The gate driving circuit 130 may be connected to one side (e.g., a left or right side) of the display panel 110. Depending on the gate driving scheme and the panel design scheme, gate driving circuits 130 may be connected with both the sides (e.g., both the left and right sides) of the display panel 110, or two or more of the four sides of the display panel 110.

The controller 140 may be a timing controller used in typical display technology, a control device that may perform other control functions as well as the functions of the timing controller, or a control device other than the timing controller, or may be a circuit in the control device. The controller 140 may be implemented as various circuits or electronic components, such as an integrated circuit (IC), a field programmable gate array (FPGA), an application specific integrated circuit (ASIC), or a processor.

The controller 140 may be mounted on a printed circuit board or a flexible printed circuit and may be electrically connected with the data driving circuit 120 and the gate driving circuit 130 through the printed circuit board or the flexible printed circuit.

The controller 140 may transmit/receive signals to/from the data driving circuit 120 according to one or more predetermined interfaces. The interface may include, e.g., a low voltage differential signaling (LVDS) interface, an embedded clock point to point interface (EPI), and a serial peripheral interface (SPI).

The controller 140 may include a storage medium, such as one or more registers.

Referring to FIG. 1, a display device 100 according to embodiments of the disclosure may include one or more optical electronic devices. The one or more optical electronic devices may be devices that receive the light transmitted through the display panel and perform a predetermined function according to the received light. For example, one or more optical electronic devices may include one or more of a photographing device, such as a camera (image sensor), a proximity sensor, an illumination sensor, and a thing or human body recognition sensor.

Referring to FIG. 1, the display device 100 according to embodiments of the disclosure may include a camera area 160 and a sensor area 170. The camera area 160 may be an area overlapping the photographing device, and the sensor area 170 may be an area overlapping the sensor device.

Referring to FIG. 1, the camera area 160 and the sensor area 170 may be disposed in the non-display area NDA, but are not limited thereto. For example, the camera area 160 and the sensor area 170 may be disposed in the display area DA. Further, the camera area 160 may be disposed in the display area DA, and the sensor area 170 may be disposed in the non-display area NDA, or the camera area 160 may be disposed in the non-display area NDA, and the sensor area 170 may be disposed in the display area DA.

The display device 100 according to the present embodiments may be a display including a backlight unit, such as a liquid crystal display, or may be a self-emission display, such as an organic light emitting display device, a quantum dot display device, or an inorganic light emitting display device.

When the display device 100 according to the present embodiments is an organic light emitting display device, each subpixel SP may include an organic light emitting diode (OLED), which is self-emissive, as the light emitting element.

If the display device 100 according to the present embodiments is a quantum dot display device, each subpixel SP may include a light emitting element formed of a quantum dot, which is a self-emission semiconductor crystal.

If the display device 100 according to the present embodiments is an inorganic light emitting display device, each subpixel SP may include an inorganic light emitting element, which is self-emissive and formed of an inorganic material, as the light emitting element. For example, the inorganic light emitting element is also called a micro light emitting diode (LED), and the inorganic light emitting display device is also called a micro-LED display device.

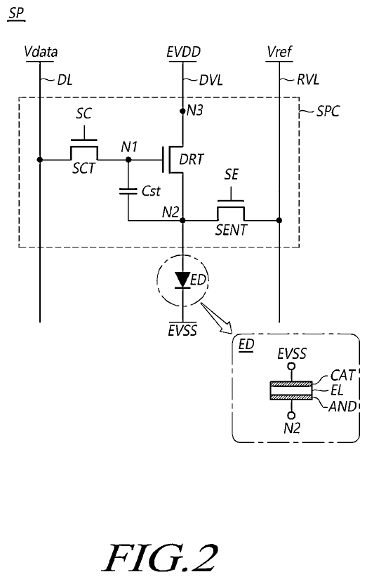

FIG. 2 is an equivalent circuit diagram illustrating a subpixel SP in a display panel 110 according to embodiments of the disclosure.

Referring to FIG. 2, each of the plurality of subpixels SP disposed on the display panel 110 according to embodiments of the disclosure may include a light emitting element ED and a subpixel circuit SPC for driving the light emitting element ED.

The subpixel circuit SPC of each subpixel SP may include a driving transistor DRT, a scan transistor SCT, a sensing transistor SENT, and a storage capacitor Cst. In this case, as the subpixel circuit SPC of each subpixel SP includes three transistors DRT, SCT, and SENT, and one capacitor Cst, it may be referred to as having a 3T (transistor) 1C (capacitor) structure.

Referring to FIG. 2, the light emitting element ED may include an anode electrode AND and a cathode electrode CAT and may include a light emitting layer EL positioned between the anode electrode AND and the cathode electrode CAT.

One of the anode electrode AND and the cathode electrode CAT may be a pixel electrode connected to a transistor, such as the driving transistor DRT, and the other may be a common electrode to which the common voltage is applied. Here, the pixel electrode is an electrode disposed in each subpixel SP, and the common electrode is an electrode commonly disposed in all subpixels SP. For example, the common voltage may be a high-potential voltage EVDD which is a high-level common voltage or a low-potential voltage EVSS which is a low-level common voltage. Here, the high-potential voltage EVDD is also referred to as a driving voltage, and the low-potential voltage EVSS is also referred to as a base voltage.

According to the example shown in FIG. 2, the anode electrode AND may be a pixel electrode connected to a transistor, such as the driving transistor DRT, and the cathode electrode CAT may be a common electrode to which the low-potential voltage EVSS is applied.

For example, the light emitting element ED may be an organic light emitting diode OLED, an inorganic material-based light emitting diode LED, or a quantum dot light emitting element.

Referring to FIG. 2, the driving transistor DRT is a transistor for driving the light emitting element ED, and may include a first node N1, a second node N2, and a third node N3.

The first node N1 of the driving transistor DRT may be a gate node of the driving transistor DRT, and may be electrically connected with a source node or a drain node of the scan transistor SCT. The second node N2 of the driving transistor DRT may be a source node or a drain node of the driving transistor DRT, and may be electrically connected with a source node or a drain node of the sensing transistor SENT and may also be electrically connected with the anode electrode AND of the light emitting element ED. The third node N3 of the driving transistor DRT may be electrically connected with a high-potential voltage line DVL supplying a high-potential voltage EVDD.

Referring to FIG. 2, the scan transistor SCT may be controlled by a scan signal SC, which is a type of gate signal, and may be connected between the first node N1 of the driving transistor DRT and the data line DL. In other words, the scan transistor SCT may be turned on or off according to the scan signal SC supplied from the scan signal line SCL, which is a type of the gate line GL, controlling the connection between the data line DL and the first node N1 of the driving transistor DRT.

The scan transistor SCT may be turned on by the scan signal SC having a turn-on level voltage and transfer the data voltage Vdata supplied from the data line DL to the first node N1 of the driving transistor DRT.

If the scan transistor SCT is an n-type transistor, the turn-on level voltage of the scan signal SC may be a high level voltage. If the scan transistor SCT is a p-type transistor, the turn-on level voltage of the scan signal SC may be a low level voltage. Hereinafter, the scan transistor SCT is exemplified as an n-type transistor. Accordingly, the turn-on level voltage is exemplified as a high-level voltage.

Referring to FIG. 2, the sensing transistor SENT may be controlled by a sensing signal SE, which is a type of gate signal, and may be connected between the second node N2 of the driving transistor DRT and the reference voltage line RVL. In other words, the sensing transistor SENT may be turned on or off according to the sensing signal SE supplied from the sensing signal line SENL, which is another type of the gate line GL, controlling the connection between the reference voltage line RVL and the second node N2 of the driving transistor DRT.

The sensing transistor SENT may be turned on by the sensing signal SE having a turn-on level voltage and transfer a reference voltage Vref supplied from the reference voltage line RVL to the second node N2 of the driving transistor DRT. Here, the sensing signal SE may be viewed as a second scan signal that is different from the scan signal SC.

The sensing transistor SENT may be turned on by the sensing signal SE having a turn-on level voltage, transferring the voltage of the second node N2 of the driving transistor DRT to the reference voltage line RVL.

If the sensing transistor SENT is an n-type transistor, the turn-on level voltage of the sensing signal SE may be a high level voltage. If the sensing transistor SENT is a p-type transistor, the turn-on level voltage of the sensing signal SE may be a low level voltage. Hereinafter, the sensing transistor SENT is exemplified as an n-type transistor. Accordingly, the turn-on level voltage is exemplified as a high-level voltage.

The function in which the sensing transistor SENT transfers the voltage of the second node N2 of the driving transistor DRT to the reference voltage line RVL may be used upon driving to sense the characteristic value of the subpixel SP. In this case, the voltage transferred to the reference voltage line RVL may be a voltage for calculating the characteristic value of the subpixel SP or a voltage reflecting the characteristic value of the subpixel SP.

In the disclosure, the characteristic value of the subpixel SP may be a characteristic value of the driving transistor DRT or the light emitting element ED. For example, the characteristic value of the driving transistor DRT may include a threshold voltage and mobility of the driving transistor DRT. The characteristic value of the light emitting element ED may include a threshold voltage of the light emitting element ED.

Referring to FIG. 2, the storage capacitor Cst may be connected between the first node N1 and second node N2 of the driving transistor DRT. The storage capacitor Cst may be charged with the quantity of electric charge corresponding to the voltage difference between both ends thereof and may serve to maintain the voltage difference between both ends for a predetermined frame time. Accordingly, during the predetermined frame time, the corresponding subpixel SP may emit light.

Referring to FIG. 2, each of the driving transistor DRT, the scan transistor SCT, and the sensing transistor SENT may be an n-type transistor or a p-type transistor. In the disclosure, for convenience of description, each of the driving transistor DRT, the scan transistor SCT, and the sensing transistor SENT is an n-type transistor.

The storage capacitor Cst is not a parasitic capacitor (e.g., Cgs or Cgd) which is an internal capacitor existing between the gate node and the source node (or drain node) of the driving transistor DRT, but may be an external capacitor intentionally designed outside the driving transistor DRT.

The subpixel SP illustrated in FIG. 2 is merely an example, and various changes may be made thereto, e.g., such as further including one or more transistors or one or more capacitors.

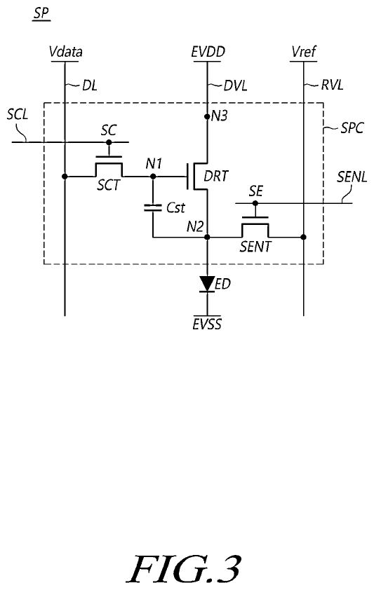

FIG. 3 is an equivalent circuit diagram illustrating a subpixel SP having a 2-gate driving structure in a display panel 110 according to embodiments of the disclosure.

The subpixel circuit SPC of the subpixel SP of FIG. 3 has the same 3TIC structure as that of FIG. 2. The subpixel SP of FIG. 3 may have a 2-gate driven structure.

As shown in FIG. 3, when the subpixel SP has a 2-gate driven structure, the subpixel SP may be connected to two gate lines GL including the scan signal line SCL and the sensing signal line SENL.

Referring to FIG. 3, in the subpixel circuit SPC of the subpixel SP having the 2-gate driven structure, the gate node of the scan transistor SCT may be connected to the scan signal line SCL, and the gate node of the sensing transistor SENT may be connected to the sensing signal line SENL. Accordingly, the scan transistor SCT and sensing transistor SENT may operate independently of each other.

Referring to FIG. 3, the subpixel circuit SPC of the subpixel SP having 2-gate driven structure may receive the scan signal SC through the scan signal line SCL and receive the sensing signal SE through the sensing signal line SENL. In the subpixel circuit SPC of the subpixel SP having the 2-gate driven structure, the gate node of the scan transistor SCT may receive the scan signal SC through the scan signal line SCL, and the gate node of the sensing transistor SENT may receive the sensing signal SE through the sensing signal line SENL.

Referring to FIG. 3, when the subpixel SP has the 2-gate driven structure, the on-off timings of the scan transistor SCT and the on-off timings of the sensing transistor SENT in one subpixel SP may be independent. In other words, when the subpixel SP has the 2-gate driven structure, the on-off timings of the scan transistor SCT and the on-off timings of the sensing transistor SENT in one subpixel SP may be different or identical.

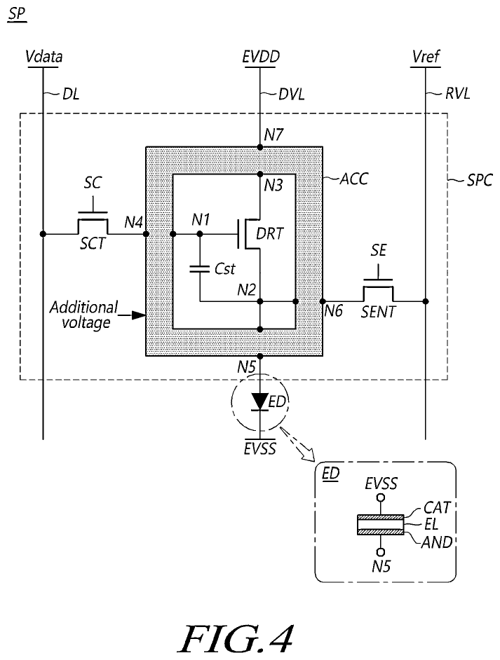

FIG. 4 is another equivalent circuit diagram illustrating a subpixel SP in a display panel 110 according to embodiments of the disclosure.

Referring to FIG. 4, the subpixel SP may include a light emitting element ED and a subpixel circuit SPC for driving the light emitting element ED. The subpixel circuit SPC may include an additional control circuit ACC in addition to a driving transistor DRT, a scan transistor SCT, a sensing transistor SENT, a storage capacitor Cst.

The additional control circuit ACC may include one or more transistors and/or one or more capacitors.

The additional control circuit ACC may include a fourth node N4 electrically connected to the source node or the drain node of the scan transistor SCT, a fifth node N5 electrically connected to the anode electrode AND of the light emitting element ED, a sixth node N6 electrically connected to the source node or the drain node of the sensing transistor SENT, and a seventh node N7 electrically connected to the high-potential voltage line DVL.

The additional control circuit ACC may be supplied with additional voltage, if required.

Referring to FIG. 4, when the fourth node N4 and the first node N1 are electrically connected, the fifth node N5, the sixth node N6, and the second node N2 are electrically connected, and the seventh node N7 and the third node N3 are electrically connected by the additional control circuit ACC, the subpixel SP of FIG. 4 may be the same as or substantially the same as the subpixel SP of FIG. 2.

For example, the additional control circuit ACC may include an emission control transistor that controls connection between the second node N2 and the fifth node N5. As another example, the additional control circuit ACC may include an emission control transistor that controls the connection between the seventh node N7 and the third node N3.

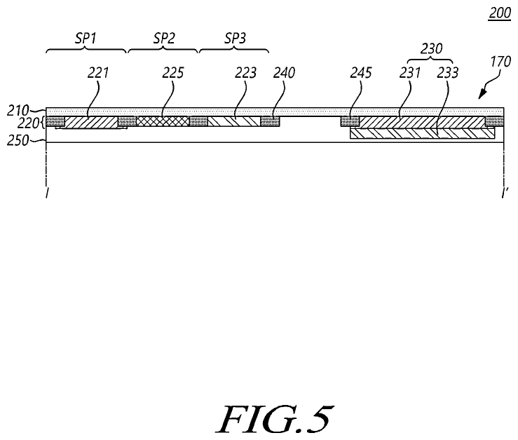

FIG. 5 is a view illustrating a color filter substrate 200 according to embodiments of the disclosure. For example, FIG. 5 is a cross-sectional view illustrating the color filter substrate 200 of the cross section taken along I-I′ of FIG. 5.

Referring to FIG. 5, the color filter substrate 200 according to embodiments of the disclosure includes a substrate 210, a color filter layer 220, a color pattern stack 230, and a planarization layer 250.

The substrate 210 may be a transparent substrate. The transparent substrate may be formed of glass or transparent plastic, such as polyimide, but is not limited thereto. The substrate 210 may be provided on the light exit portion of the display device 100 to prevent or at least reduce penetration of oxygen or moisture from the external environment, and may transmit light implemented in the color filter layer 220.

Referring to FIG. 5, the substrate 210 may include a plurality of subpixels SP and the sensor area 170.

The plurality of subpixels SP may include a first subpixel SP1, a second subpixel SP2, and a third subpixel SP3. The first subpixel SP1 may emit light of a first color, the second subpixel SP2 may emit light of a second color, and the third subpixel SP3 may emit light of a third color, but the disclosure is not limited thereto.

For example, the first subpixel SP1 may be a red (R) subpixel that emits red (R) light, which is light of the first color, the second subpixel SP2 may be a blue (B) subpixel that emits blue (B) light, which is light of the second color, and the third subpixel SP3 may be a green (G) subpixel that emits green (G) light, which is light of the third color.

Referring to FIG. 5, a color filter layer 220 may include a plurality of color filters on the substrate 210. The color filters include a first color filter 221, a second color filter 225, and a third color filter 225 of different colors and positioned in respective areas corresponding to the plurality of subpixels SP.

At least two of the first color filter 221, the second color filter 223, and the third color filter 225 may have different thicknesses. For example, one color filter may have a thickness that is larger than the other two color filters, and the other two color filters may have the same or substantially same thickness. Further, all of the three color filters may have different thicknesses.

The first color filter 221 may be a red (R) color filter which has the first color, the second color filter 223 may be a blue (B) color filter which has the second color, and the third color filter 225 may be a green (G) color filter which has the third color. In other words, the red (R) color filter, the blue (B) color filter, and the green (G) color filter may be formed using red (R), blue (B), and green (G) color resins, respectively.

Meanwhile, although not illustrated in FIG. 5, the color filter layer 220 may further include a transparent area in which no color filter is disposed. That is, the transparent area lacks any color filter. In the transparent area, a transparent planarization layer 250 may be disposed without using a separate color resin.

The transparent area may be used as a white (W) subpixel emitting white (W) light or a transmission area through which external light passes. For example, when the white light emitting element is disposed in the transparent area, the transparent area may operate as a white (W) subpixel. Further, when no light emitting element is disposed in the transparent area, the transparent area may operate as a transmissive area through which external light passes and may be used in the transparent display device.

Referring to FIG. 5, a black matrix 240 defining an opening area exposing each of the plurality of subpixels SP may be positioned on the substrate 210.

The first subpixel SP1, the second subpixel SP2, and the third subpixel SP3 each may be provided with a black matrix 240 between the respective subpixel areas, and the respective subpixel areas may be divided by the black matrix 240.

In other words, the black matrix 240 may allow light emitted from the light emitting element to be emitted only from each of the first subpixel SP1, the second subpixel SP2, and the third subpixel SP3. Accordingly, the black matrix 240 may prevent or reduce colors from mixing at the boundary of each subpixel area.

Referring to FIG. 5, a color pattern stack 230 positioned to correspond to the sensor area 170 may be disposed on the substrate 210. That is, the color pattern stack 230 is in the sensor area 170. The color pattern stack 230 may be disposed on the same layer as the color filter layer 220.

The color pattern stack 230 may be configured by stacking color patterns of different colors. The color pattern stack 230 may be configured by stacking color patterns of different colors, thereby operating as an infrared filter that selectively transmits infrared light by decreasing the transmittance of visible light and increasing the transmittance of infrared light.

The color pattern stack 230 may have a thickness of 1 μm to 5 μm. In other words, the total thickness of the color pattern stack 230 may be 1 μm to 5 μm. If the color pattern stack 230 has a thickness of less than 1 μm, the transmittance of visible light may be relatively high, and if the color pattern stack 230 has a thickness of more than 5 μm, the transmittance of visible light may be effectively decreased, but the thickness of the color filter substrate 200 including the color pattern stack 230 may be increased.

Referring to FIG. 5, the color pattern stack 230 may be configured by stacking the first color pattern 231 and the second color pattern 233 of different colors. For example, the color pattern stack 230 may have a stacked structure in which the first color pattern 231 is disposed on the substrate 210 and the second color pattern 233 is disposed on the first color pattern 231. Here, the first color pattern 231 may be a red (R) color pattern which has the first color, and the second color pattern 233 may be a blue (B) color pattern which has the second color.

The first color pattern 231 and the second color pattern 233 constituting the color pattern stack 230 may have different thicknesses. For example, the first color pattern 231 may have a first thickness that is thicker than a second thickness of the second color pattern 233.

The first color pattern 231 may have the same or substantially same thickness and color as the first color filter 221, and the second color pattern 233 may have the same or substantially same thickness and color as the second color filter 223.

The color pattern stack 230 may be formed simultaneously with the color filter layer 220. For example, the first color pattern 231 may be simultaneously formed when the first color filter 221 is formed, and then the second color pattern 233 may be simultaneously formed when the second color filter 223 is formed.

Referring to FIG. 5, a pattern defining layer 245 defining an area in which the color pattern stack 230 is disposed may be positioned on the substrate 210. The pattern defining layer 245 may be formed simultaneously with the black matrix 240.

Referring to FIG. 5, the planarization layer 250 may be positioned on the color filter layer 220 and the color pattern stack 230. The planarization layer 250 may be disposed to cover the color filter layer 220, the color pattern stack 230, the black matrix 240, and the pattern defining layer 245.

The planarization layer 250 may alleviate or planarize a step between the color filter layer 220, the color pattern stack 230, the black matrix 240, and the pattern defining layer 245 constituting the color filter substrate 200.

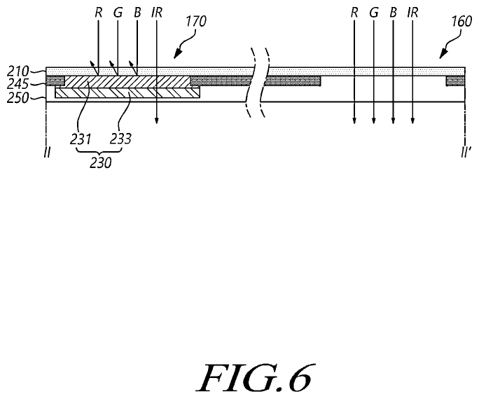

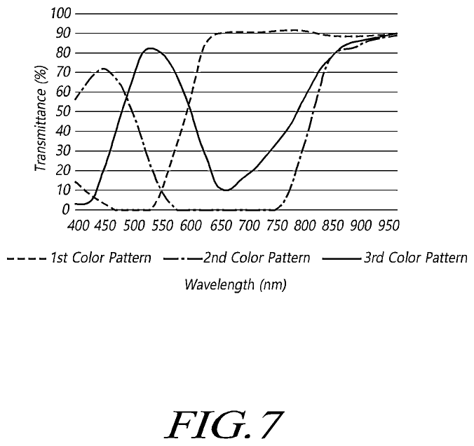

FIG. 6 is a view illustrating a sensor area 170 and a camera area 160 in a color filter substrate 200 according to embodiments of the disclosure. For example, FIG. 6 is a cross-sectional view illustrating a portion of the color filter substrate 200 in the cross section taken along II-II′ of FIG. 1. FIG. 7 is a graph illustrating the light transmittance according to color filters in a color filter substrate 200 according to embodiments of the disclosure. Those identical or similar to what has been described with reference to FIGS. 1 to 5 are omitted from the following description or are briefly described.

Referring to FIG. 6, as no color pattern is disposed under the substrate 210 in the camera area 160, visible light R, G, and B and infrared light IR may pass through the substrate 210.

In contrast, in the sensor area 170, the color pattern stack 230 configured by stacking the first color pattern 231 and the second color pattern 233 may be disposed under the substrate 210, so that the color pattern stack 230 may block the visible light R, G, and B while transmitting infrared light IR.

Referring to FIG. 7, it may be identified that the first color pattern transmits light of a wavelength of about 630 nm or more, the second color pattern transmits light around a wavelength of about 450 nm and light of a wavelength of about 830 nm or more, and the third color pattern transmits light around a wavelength of about 530 nm and light of a wavelength of about 830 nm or more, and blocks light of other wavelengths.

Referring to FIGS. 6 and 7, the color pattern stack 230 may be configured by stacking the first color pattern 231 and the second color pattern 233, thereby blocking visible light R, G, and B and transmitting infrared light IR.

In other words, as external light including visible light R, G, and B and infrared light IR passes through the first color pattern 231, light R and IR having a wavelength of about 630 nm or more may be transmitted, and light G and B having a wavelength less than about 630 nm may be blocked. As the light R and IR transmitted through the first color pattern 231 passes through the second color pattern 231, the light IR having a wavelength of about 830 nm or more may be transmitted, and the light R having a wavelength less than about 830 nm may be blocked, thereby implementing an infrared filter that blocks visible light R, G, and B and selectively transmits infrared light IR, with the color pattern stack 230.

The color pattern stack 230 included in the color filter substrate 200 according to embodiments of the disclosure may implement an infrared filter having a high transmittance of 80% or more in an infrared (IR) wavelength band.

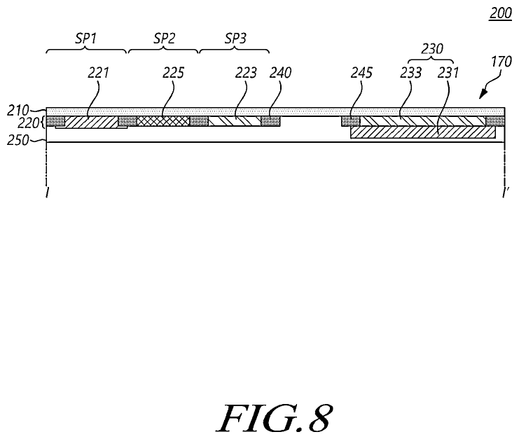

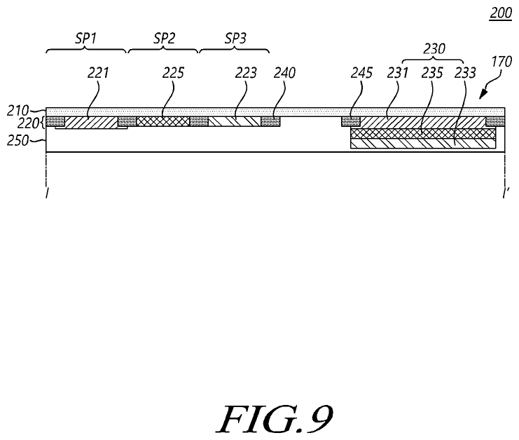

FIGS. 8 and 9 are views illustrating a color filter substrate 200 according to embodiments of the disclosure. For example, FIG. 8 is a view illustrating an example in which the stacked order of color patters of the color pattern stack 230 differ, and FIG. 9 is a view illustrating an example in which the numbers of stacked color patterns of the color pattern stack 230 differ. What is identical or similar to those described with reference to FIGS. 1 to 7 is omitted from the following description or briefly described below.

Referring to FIG. 8, a color filter substrate 200 according to embodiments of the disclosure includes a substrate 210, a color filter layer 220, a color pattern stack 230, and a planarization layer 250.

Referring to FIG. 8, the color pattern stack 230 positioned to correspond to the sensor

area 170 may be disposed on the substrate 210. That is, the color pattern stack 230 is in the sensor area 170. The color pattern stack 230 may be disposed on the same layer as the color filter layer 220.

Referring to FIG. 8, the color pattern stack 230 may be configured by stacking the first color pattern 231 and the second color pattern 233 of different colors. For example, the color pattern stack 230 may have a stacked structure in which the second color pattern 233 is disposed on the substrate 210 and the first color pattern 231 is disposed on the second color pattern 233. Here, the first color pattern 231 may be a red (R) color pattern which has the first color, and the second color pattern 233 may be a blue (B) color pattern which has the second color.

Referring to FIG. 8, the color pattern stack 230 may be configured by stacking color patterns of different colors, thereby operating as an infrared filter that selectively transmits infrared light by decreasing the transmittance of visible light and increasing the transmittance of infrared light.

The first color pattern 231 and the second color pattern 233 constituting the color pattern stack 230 may have different thicknesses. For example, the first color pattern 231 may be thicker than the second color pattern 233.

The first color pattern 231 may have the same or substantially same thickness and color as the first color filter 221, and the second color pattern 233 may have the same or substantially same thickness and color as the second color filter 223.

The color pattern stack 230 may be formed simultaneously with the color filter layer 220. For example, the second color pattern 233 may be simultaneously formed when the second color filter 223 is formed, and then the first color pattern 231 may be simultaneously formed when the first color filter 221 is formed.

Referring to FIG. 8, as external light including visible light R, G, and B and infrared light IR may pass through the second color pattern 233, light B and G around a wavelength of about 450 nm and light IR of a wavelength of about 830 nm may be transmitted, and red R light and part of green G light may be blocked. As the light B, G, and IR transmitted through the second color pattern 233 passes through the first color pattern 231, the light IR having a wavelength of about 630 nm or more may be transmitted, and the light B and G having a wavelength less than about 630 nm may be blocked, thereby implementing an infrared filter that blocks visible light R, G, and B and selectively transmits infrared light IR, with the color pattern stack 230.

Referring to FIG. 9, the color pattern stack 230 may be configured by stacking a first color pattern 231, a second color pattern 233, and a third color pattern 235 of different colors. The third color pattern 235 is on at least one of the first color pattern 231 or the second color pattern 233. For example, the color pattern stack 230 may have a stacked structure in which the first color pattern 231, the second color pattern 233, and the third color pattern 235 are sequentially disposed on the substrate 210. In another example, the color pattern stack 230 has a stacked structure including the first color pattern 231, the third color pattern 235 on the first color pattern 231, and the second color pattern 233 on the third color pattern 235 as shown in FIG. 9. Here, the first color pattern 231 may be a red (R) color pattern which has the first color, the second color pattern 233 may be a blue (B) color pattern which has the second color, and the third color pattern 235 may be a green (G) color pattern which has the third color.

Referring to FIG. 9, the color pattern stack 230 may be configured by stacking color patterns of different colors, thereby operating as an infrared filter that selectively transmits infrared light by decreasing the transmittance of visible light and increasing the transmittance of infrared light.

The first color pattern 231, the second color pattern 233, and the third color pattern 235 constituting the color pattern stack 230 may have different thicknesses. For example, the first color pattern 231 may be thicker than the second color pattern 233 and the third color pattern 235. Further, the thickness of the color pattern may decrease in the order of the first color pattern 231, the second color pattern 233, and the third color pattern 235.

The first color pattern 231 may have the same or substantially same thickness and color as the first color filter 221, the second color pattern 233 may have the same or substantially same thickness and color as the second color filter 223, and the third color pattern 235 may have the same or substantially same thickness and color as the third color filter 225.

The color pattern stack 230 may be formed simultaneously with the color filter layer 220. For example, the second color pattern 233 may be simultaneously formed when the second color filter 223 is formed, and then the first color pattern 231 may be simultaneously formed when the first color filter 221 is formed.

The color pattern stack 230 may be formed simultaneously with the color filter layer 220. For example, the first color pattern 231 may be simultaneously formed when the first color filter 221 is formed, the second color pattern 233 may be simultaneously formed when the second color filter 223 is formed, and finally, the third color pattern 235 may be simultaneously formed when the third color filter 225 is formed.

Referring to FIG. 9, as external light including visible light R, G, and B and infrared light IR passes through the first color pattern 231, light R and IR having a wavelength of about 630 nm or more may be transmitted, and light G and B having a wavelength less than about 630 nm may be blocked. As the light R and IR transmitted through the first color pattern 231 passes through the second color pattern 231, the light IR having a wavelength of about 830 nm or more may be transmitted, and the light R having a wavelength less than about 830 nm may be blocked. As the light IR transmitted through the second color pattern 233 passes through the third color pattern 235, partially transmitted red (R) light may be blocked, implementing an infrared filter that blocks the visible light R, G, and B and selectively transmits the infrared light IR, with the color pattern stack 230.

The color filter substrate 200 according to embodiments of the disclosure may include the color pattern stack 230 by stacking color patterns having the same or substantially same configuration as the color filter layer 220, thereby implementing an infrared filter that selectively transmits infrared light.

The color filter substrate 200 according to embodiments of the disclosure may have the color pattern stack 230 by stacking a color pattern having the same or substantially same configuration as the color filter layer 220, thereby implementing an infrared filter that reduces external visibility without having a separate infrared ink.

In the color filter substrate 200 according to embodiments of the disclosure, the color pattern stack 230 may be formed by simultaneously stacking a color pattern having the same or substantially same configuration as the color filter layer 220, achieving process optimization with a simplified manufacturing process.

In the color filter substrate 200 according to embodiments of the disclosure, the color pattern stack 230 may be formed by simultaneously stacking a color pattern having the same or substantially same configuration as the color filter layer 220, enabling implementation of a uni-material product.

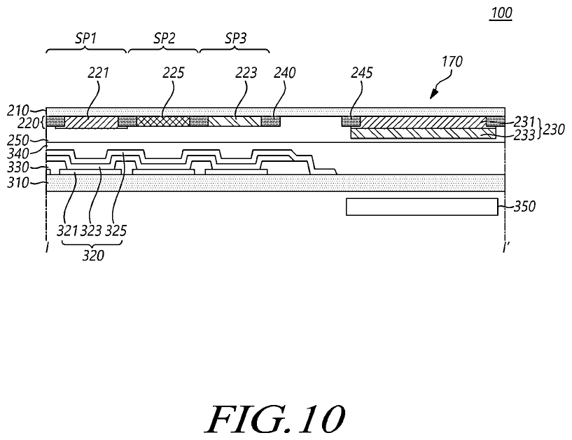

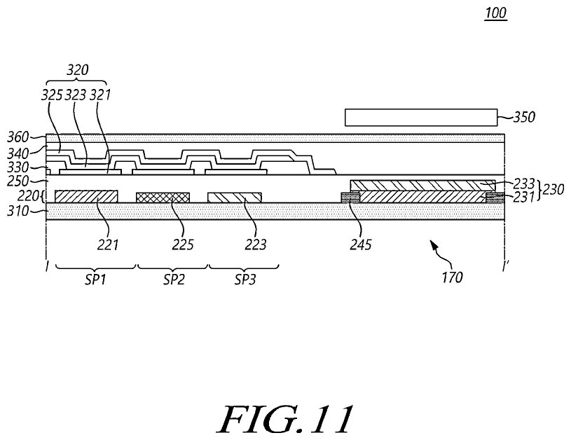

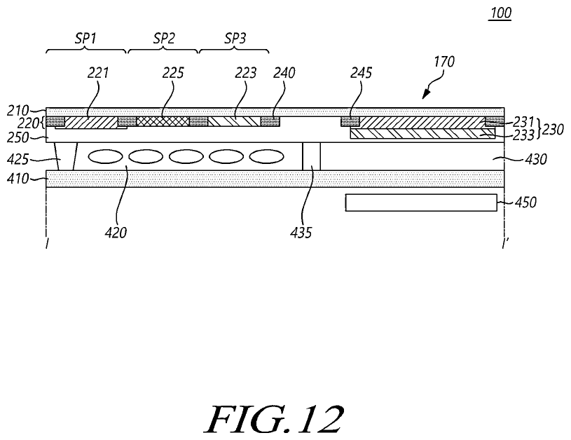

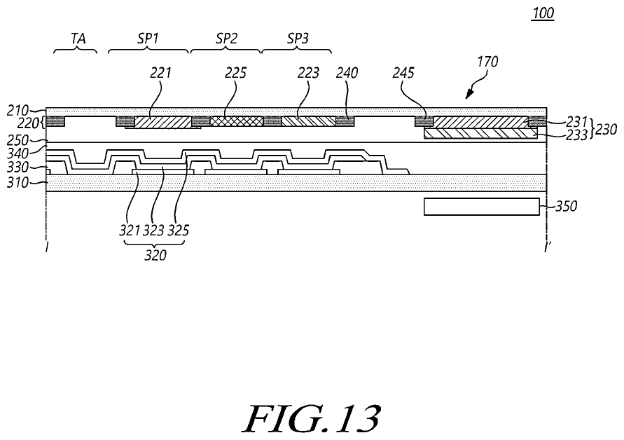

FIGS. 10, 11, 12, and 13 are views illustrating a display device 100 according to embodiments of the disclosure. For example, FIG. 10 is a view illustrating a display device 100 having a top emission structure, FIG. 11 is a view illustrating a display device 100 having a bottom emission structure, FIG. 12 is a view illustrating a display device 100 including a liquid crystal layer, and FIG. 13 is a view illustrating a display device 100 including a transparent area. Those identical or similar to what has been described with reference to FIGS. 1 to 9 are omitted from the following description or are briefly described.

FIG. 10 is a view illustrating a display device 100 having a top emission structure.

Referring to FIG. 10, a display device 100 according to embodiments of the disclosure includes a first substrate 210, a color filter layer 220, a color pattern stack 230, a planarization layer 250, a second substrate 310, and a sensor module 350.

Referring to FIG. 10, the first substrate 210 may be a transparent substrate. The transparent substrate may be formed of glass or transparent plastic, such as polyimide, but is not limited thereto. The first substrate 210 may be provided on the light exit portion of the display device 100 to reduce or prevent oxygen or moisture from the external environment from penetrating, and may transmit light implemented in the color filter layer 220.

Referring to FIG. 10, the first substrate 210 may include the color filter layer 220 on the first substrate 210.

Referring to FIG. 10, a color filter layer 220 including first, second, and third color filters 221, 223, and 225 of different colors and positioned in respective areas corresponding to the plurality of subpixels SP may be disposed on the first substrate 210.

At least two of the first color filter 221, the second color filter 223, and the third color filter 225 may have different thicknesses. For example, one color filter may have a thickness larger than the other two color filters, and the other two color filters may have the same or substantially same thickness. Further, all of the three color filters may have different thicknesses.

The first color filter 221 may be a red (R) color filter which has the first color, the second color filter 223 may be a blue (B) color filter which has the second color, and the third color filter 225 may be a green (G) color filter which has the third color. In other words, the red (R) color filter, the blue (B) color filter, and the green (G) color filter may be formed using red (R), blue (B), and green (G) color resins, respectively.

Referring to FIG. 10, a black matrix 240 defining an opening area exposing each of the plurality of subpixels SP may be positioned on the first substrate 210.

The first subpixel SP1, the second subpixel SP2, and the third subpixel SP3 each may be provided with a black matrix 240 between the respective subpixel areas, and the respective subpixel areas may be divided by the black matrix 240.

In other words, the black matrix 240 may allow light emitted from the light emitting element to be emitted only from each of the first subpixel SP1, the second subpixel SP2, and the third subpixel SP3. Accordingly, the black matrix 240 may reduce or prevent colors from mixing at the boundary of each subpixel area.

Referring to FIG. 10, the color pattern stack 230 positioned to correspond to the sensor area 170 may be disposed on the first substrate 210. The color pattern stack 230 may be disposed on the same layer as the color filter layer 220.

The color pattern stack 230 may be configured by stacking color patterns of different colors. The color pattern stack 230 may be configured by stacking color patterns of different colors, thereby operating as an infrared filter that selectively transmits infrared light by decreasing the transmittance of visible light and increasing the transmittance of infrared light.

The color pattern stack 230 may have a thickness in a range of 1 μm to 5 μm. In other words, the total thickness of the color pattern stack 230 may be in a range of 1 μm to 5 μm. If the color pattern stack 230 has a thickness of less than 1 μm, the transmittance of visible light may be relatively high, and if the color pattern stack 230 has a thickness of more than 5 μm, the transmittance of visible light may be effectively decreased, but the thickness of the display device 100 including the color pattern stack 230 may be increased.

Referring to FIG. 10, the color pattern stack 230 may be configured by stacking the first color pattern 231 and the second color pattern 233 of different colors. For example, the color pattern stack 230 may have a stacked structure in which the first color pattern 231 is disposed on the first substrate 210 and the second color pattern 233 is disposed on the first color pattern 231. Here, the first color pattern 231 may be a red (R) color pattern which has the first color, and the second color pattern 233 may be a blue (B) color pattern which has the second color.

The first color pattern 231 and the second color pattern 233 constituting the color pattern stack 230 may have different thicknesses. For example, the first color pattern 231 may be thicker than the second color pattern 233.

The first color pattern 231 may have the same or substantially same thickness and color as the first color filter 221, and the second color pattern 233 may have the same or substantially same thickness and color as the second color filter 223.

The color pattern stack 230 may be formed simultaneously with the color filter layer 220. For example, the first color pattern 231 may be simultaneously formed when the first color filter 221 is formed, and then the second color pattern 233 may be simultaneously formed when the second color filter 223 is formed.

The color pattern stack 230 may include various embodiments of the color pattern stack 230 described in connection with FIGS. 5 to 9.

Referring to FIG. 10, a pattern defining layer 245 defining an area in which the color pattern stack 230 is disposed may be positioned on the first substrate 210. The pattern defining layer 245 may be formed simultaneously with the black matrix 240.

Referring to FIG. 10, the planarization layer 250 may be positioned on the color filter layer 220 and the color pattern stack 230. The planarization layer 250 may be disposed to cover the color filter layer 220, the color pattern stack 230, the black matrix 240, and the pattern defining layer 245.

The planarization layer 250 may alleviate or planarize a step between the color filter layer 220, the color pattern stack 230, the black matrix 240, and the pattern defining layer 245 constituting the color filter substrate 200.

Referring to FIG. 10, a second substrate 310 spaced apart from the first substrate 210 may be disposed on the planarization layer 250. The second substrate 310 may be a transparent substrate. The transparent substrate may be formed of glass or transparent plastic. The transparent substrate may be formed in a stacked structure of various transparent insulation layers.

The second substrate 310 may be a TFT substrate including a thin film transistor TFT. The TFT substrate may include various signal lines and a capacitor, as well as the thin film transistor TFT. The thin film transistor TFT may include a switching thin film transistor, a driving thin film transistor, and a sensing thin film transistor. The signal lines may include gate lines, data lines, power lines, and reference lines.

Referring to FIG. 10, a bank 330 and a light emitting element 320 may be disposed between the planarization layer 250 and the second substrate 310.

The bank 330 may be disposed on the second substrate 310 to overlap a portion of the upper surface of the first electrode 321. The bank 330 may be disposed to expose a portion of the upper surface of the first electrode 321.

The light emitting element 320 may include a first electrode 321 disposed on the second substrate 310, a light emitting layer 323 disposed on the first electrode 321, and a second electrode 325 disposed on the light emitting layer 323.

The first electrode 321 is a pixel electrode serving as an anode, and may be independently disposed in each of the subpixels.

The first electrode 321 may include a reflective metallic material having a low work function and excellent reflection efficiency. The first electrode 321 may include a reflective electrode and a transparent electrode.

For example, the reflective metal constituting the reflective electrode included in the first electrode 321 may include any one selected from the group consisting of aluminum (Al), silver (Ag), copper (Cu), magnesium (Mg), platinum (Pt), gold (Au), nickel (Ni), neodymium (Nd), iridium (Ir), and chromium (Cr), or any one of alloys including at least one thereof.

For example, the first electrode 321 may be formed in a multilayer structure of any one of a stacked structure (Ti/Al/Ti) of aluminum (Al) and titanium (Ti), a stacked structure (ITO/Al/ITO) of aluminum (Al) and ITO, an alloy of APC (Ag/Pd/Cu), and a stacked structure (ITO/APC/ITO) of APC alloy and ITO, or may be formed in a single layer structure or a multilayer structure of at least one of aluminum (Al), silver (Ag), copper (Cu), magnesium (Mg), platinum (Pt), gold (Au), nickel (Ni), neodymium (Nd), iridium (Ir), chromium (Cr), and alloys thereof.

Further, the first electrode 321 may include a reflective electrode and a transparent electrode disposed on the reflective electrode. The reflective electrode may be the above-described reflective metal, and the transparent electrode may include transparent conductive oxide (TCO) such as indium tin oxide (ITO), indium Zinc oxide (IZO), indium gallium Zinc oxide (IGZO), or the like.

The light emitting layer 323 may be an organic light emitting layer. The organic light emitting layer may include multiple layers of a hole injection layer, a hole transport layer, a light emitting material layer, an electron transport layer, and an electron injection layer to increase light emission efficiency.

The second electrode 325 is a common electrode serving as a cathode, and may be commonly disposed in all subpixels SP.

The second electrode 325 may be a semi-transmissive electrode including a semi-transmissive metal or a transparent electrode.

The second electrode 325 may include any one selected from the group consisting of aluminum (Al), silver (Ag), copper (Cu), magnesium (Mg), platinum (Pt), gold (Au), nickel (Ni), chromium (Cr), titanium (Ti), tungsten (W), tantalum (Ta), cobalt (Co), iron (Fe), and molybdenum (Mo), or any one of alloys including at least one thereof.

An encapsulation layer 340 may be disposed on the light emitting element 320.

The encapsulation layer 340 is formed on the second electrode 325 of the light emitting element 320 and serves to reduce or prevent external moisture from penetrating into the light emitting layer 323. The encapsulation layer 340 may be formed of an inorganic insulating material. Alternatively, the encapsulation layer 340 may have a structure in which a plurality of inorganic insulating materials and at least one organic insulating material are stacked. For example, the encapsulation layer 340 may be formed so that a first inorganic insulating material and a second inorganic insulating material overlap each other with an organic insulating material interposed therebetween.

Referring to FIG. 10, there may be included a sensor module 350 positioned in an area corresponding to the sensor area 170 and disposed on a rear surface of the second substrate 310. The sensor module 350 includes, but is not limited to, a proximity sensor, an illuminance sensor, or a thing and human body recognition sensor.

The sensor module 350 may be an infrared (IR) sensor module that uses an infrared wavelength band. The infrared (IR) sensor module may detect the outside of the display device using light in the infrared wavelength band.

Referring to FIG. 10, a transparent resin may be disposed between the color pattern stack 230 and the second substrate 310 in the sensor area 170. When the planarization layer 250 covers the color pattern stack 230, the transparent resin may be disposed between the planarization layer 250 and the second substrate 310.

Meanwhile, the display device 100 according to embodiments of the disclosure may further include a camera area disposed adjacent to the sensor area 170. In the camera area, a transparent resin may be disposed between the first substrate 210 and the second substrate 310. When the planarization layer 250 covers the first substrate 210, the transparent resin may be disposed between the planarization layer 250 and the second substrate 310.

The transparent resin may be disposed not to form an air gap between the color pattern stack 230 of the sensor area 170 and the second substrate 310 or between the first substrate 210 of the camera area and the second substrate 310. If an air gap is present between the color pattern stack 230 of the sensor area 170 and the second substrate 310, the light passing through the color pattern stack 230 may be scattered in the air gap, deteriorating or lowering the efficiency of light incident on the sensor module 350. If an air gap is present between the first substrate 210 and the second substrate 310 of the camera area, the light passing through the first substrate 210 may be scattered in the air gap, deteriorating or lowering the efficiency of light incident on the camera module.

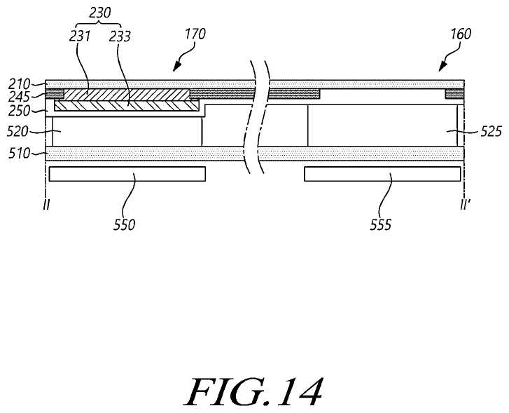

The transparent resin disposed in the sensor area and camera area is described in detail with reference to FIG. 14.

FIG. 11 is a view illustrating a display device 100 having a bottom emission structure.

Referring to FIG. 11, a display device 100 according to embodiments of the disclosure includes a first substrate 310, a color filter layer 220, a color pattern stack 230, a planarization layer 250, a second substrate 360, and a sensor module 350.

Referring to FIG. 11, the first substrate 310 may be a transparent substrate. The transparent substrate may be formed of glass or transparent plastic. The transparent substrate may be formed in a stacked structure of various transparent insulation layers.

The first substrate 310 may be a TFT substrate including a thin film transistor TFT. The TFT substrate may include various signal lines and a capacitor, as well as the thin film transistor TFT. The thin film transistor TFT may include a switching thin film transistor, a driving thin film transistor, and a sensing thin film transistor. The signal lines may include gate lines, data lines, power lines, and reference lines.

Referring to FIG. 11, the first substrate 310 may include a plurality of subpixels SP and a sensor area 170.

Referring to FIG. 11, a color filter layer 220 including first, second, and third color filters 221, 223, and 225 of different colors and positioned in respective areas corresponding to the plurality of subpixels SP may be disposed on the first substrate 310.

At least two of the first color filter 221, the second color filter 223, and the third color filter 225 may have different thicknesses. For example, one color filter may have a thickness larger than the other two color filters, and the other two color filters may have the same or substantially same thickness. Further, all of the three color filters may have different thicknesses.

The first color filter 221 may be a red (R) color filter which has the first color, the second color filter 223 may be a blue (B) color filter which has the second color, and the third color filter 225 may be a green (G) color filter which has the third color. In other words, the red (R) color filter, the blue (B) color filter, and the green (G) color filter may be formed using red (R), blue (B), and green (G) color resins, respectively.

Referring to FIG. 11, the color pattern stack 230 positioned to correspond to the sensor area 170 may be disposed on the first substrate 310. The color pattern stack 230 may be disposed on the same layer as the color filter layer 220.

The color pattern stack 230 may be configured by stacking color patterns of different colors. The color pattern stack 230 may be configured by stacking color patterns of different colors, thereby operating as an infrared filter that selectively transmits infrared light by decreasing the transmittance of visible light and increasing the transmittance of infrared light.

The color pattern stack 230 may have a thickness of 1 μm to 5 μm. In other words, the total thickness of the color pattern stack 230 may be 1 μm to 5 μm. If the color pattern stack 230 has a thickness of less than 1 μm, the transmittance of visible light may be relatively high, and if the color pattern stack 230 has a thickness of more than 5 μm, the transmittance of visible light may be effectively decreased, but the thickness of the display device 100 including the color pattern stack 230 may be increased.

Referring to FIG. 11, the color pattern stack 230 may be configured by stacking the first color pattern 231 and the second color pattern 233 of different colors. For example, the color pattern stack 230 may have a stacked structure in which the first color pattern 231 is disposed on the first substrate 310 and the second color pattern 233 is disposed on the first color pattern 231. Here, the first color pattern 231 may be a red (R) color pattern which has the first color, and the second color pattern 233 may be a blue (B) color pattern which has the second color.

The first color pattern 231 and the second color pattern 233 constituting the color pattern stack 230 may have different thicknesses. For example, the first color pattern 231 may be thicker than the second color pattern 233.

The first color pattern 231 may have the same or substantially same thickness and color as the first color filter 221, and the second color pattern 233 may have the same or substantially same thickness and color as the second color filter 223.

The color pattern stack 230 may be formed simultaneously with the color filter layer 220. For example, the first color pattern 231 may be simultaneously formed when the first color filter 221 is formed, and then the second color pattern 233 may be simultaneously formed when the second color filter 223 is formed.

The color pattern stack 230 may include various embodiments of the color pattern stack 230 described in connection with FIGS. 5 to 10.

Referring to FIG. 11, a pattern defining layer 245 defining an area in which the color pattern stack 230 is disposed may be positioned on the first substrate 310.

Referring to FIG. 11, the planarization layer 250 may be positioned on the color filter layer 220 and the color pattern stack 230. The planarization layer 250 may be disposed to cover the color filter layer 220, the color pattern stack 230, and the pattern defining layer 245.

The planarization layer 250 may alleviate or planarize a step between the color filter layer 220, the color pattern stack 230, and the pattern defining layer 245 constituting the color filter substrate 200.

Referring to FIG. 11, a bank 330 and a light emitting element 320 may be disposed between the planarization layer 250 and the second substrate 360.

The bank 330 may be disposed on the planarization layer 250 to overlap a portion of the upper surface of the first electrode 321. The bank 330 may be disposed to expose a portion of the upper surface of the first electrode 321.

The light emitting element 320 may include a first electrode 321 disposed on the planarization layer 250, a light emitting layer 323 disposed on the first electrode 321, and a second electrode 325 disposed on the light emitting layer 323.

The first electrode 321 is a pixel electrode serving as an anode, and may be independently disposed in each of the subpixels.

The first electrode 321 may be a transparent electrode including a transparent conductive material.

For example, the transparent conductive material included in the first electrode 321 may include any one of indium-tin-oxide (ITO), indium-zinc-oxide (IZO), indium-gallium-zinc-oxide (IGZO), indium-tin-zinc-oxide (ITZO), zinc-tin-oxide (ZTO), fluorine-tin-oxide (FTO), aluminum-zinc-oxide (AZO), antimony-tin-oxide (ATO), titanium oxide (TiO₂), indium oxide (In₂O₃), tin oxide (SnO₂), zinc oxide (ZnO), and silver-magnesium (Ag—Mg) alloys.

The light emitting layer 323 may be an organic light emitting layer. The organic light emitting layer may include multiple layers of a hole injection layer, a hole transport layer, a light emitting material layer, an electron transport layer, and an electron injection layer to increase light emission efficiency.

The second electrode 325 is a common electrode serving as a cathode, and may be commonly disposed in all subpixels SP.

The second electrode 325 may include a reflective electrode and a transparent electrode.

For example, the reflective metal constituting the reflective electrode included in the second electrode 325 may include any one selected from the group consisting of aluminum (Al), silver (Ag), copper (Cu), magnesium (Mg), platinum (Pt), gold (Au), nickel (Ni), neodymium (Nd), iridium (Ir), and chromium (Cr), or any one of alloys including at least one thereof.

For example, the second electrode 325 may be formed in a multilayer structure of any one of a stacked structure (Ti/Al/Ti) of aluminum (Al) and titanium (Ti), a stacked structure (ITO/Al/ITO) of aluminum (Al) and ITO, an alloy of APC (Ag/Pd/Cu), and a stacked structure (ITO/APC/ITO) of APC alloy and ITO, or may be formed in a single layer structure or a multilayer structure of at least one of aluminum (Al), silver (Ag), copper (Cu), magnesium (Mg), platinum (Pt), gold (Au), nickel (Ni), neodymium (Nd), iridium (Ir), chromium (Cr), and alloys thereof.

Further, the second electrode 325 may include a reflective electrode and a transparent electrode disposed under the reflective electrode. The reflective electrode may be the above-described reflective metal, and the transparent electrode may include transparent conductive oxide (TCO) such as indium tin oxide (ITO), indium Zinc oxide (IZO), indium gallium Zinc oxide (IGZO), or the like.

An encapsulation layer 340 may be disposed on the light emitting element 320.

The encapsulation layer 340 is formed on the second electrode 325 of the light emitting element 320 and serves to reduce or prevent external moisture from penetrating into the light emitting layer 323. The encapsulation layer 340 may be formed of an inorganic insulating material. Alternatively, the encapsulation layer 340 may have a structure in which a plurality of inorganic insulating materials and at least one organic insulating material are stacked. For example, the encapsulation layer 340 may be formed so that a first inorganic insulating material and a second inorganic insulating material overlap each other with an organic insulating material interposed therebetween.

The second substrate 360 may be disposed on the encapsulation layer 340.

The second substrate 360 may be a transparent substrate. The transparent substrate may be formed of glass or transparent plastic, such as polyimide, but is not limited thereto.

Referring to FIG. 11, there may be included a sensor module 350 positioned in an area corresponding to the sensor area 170 and disposed on a rear surface of the second substrate 360. The sensor module 350 includes, but is not limited to, an illuminance sensor, or a thing and human body recognition sensor.

The sensor module 350 may be an infrared (IR) sensor module that uses an infrared wavelength band. The infrared (IR) sensor module may detect the outside of the display device using light in the infrared wavelength band.

Referring to FIG. 11, a transparent resin may be disposed between the color pattern stack 230 and the second substrate 360 in the sensor area 170. When the planarization layer 250 covers the color pattern stack 230, the transparent resin may be disposed between the planarization layer 250 and the second substrate 360.

Meanwhile, the display device 100 according to embodiments of the disclosure may further include a camera area disposed adjacent to the sensor area 170. In the camera area, a transparent resin may be disposed between the first substrate 310 and the second substrate 360. When the planarization layer 250 covers the first substrate 310, the transparent resin may be disposed between the planarization layer 250 and the second substrate 360.

The transparent resin may be disposed not to form an air gap between the color pattern stack 230 of the sensor area 170 and the second substrate 360 or between the first substrate 310 of the camera area and the second substrate 360. If an air gap is present between the color pattern stack 230 of the sensor area 170 and the second substrate 360, the light passing through the color pattern stack 230 may be scattered in the air gap, deteriorating or lowering the efficiency of light incident on the sensor module 350. If an air gap is present between the first substrate 310 and the second substrate 360 of the camera area, the light passing through the first substrate 310 may be scattered in the air gap, deteriorating or lowering the efficiency of light incident on the camera module.

The transparent resin disposed in the sensor area and camera area is described in detail with reference to FIG. 14.

FIG. 12 is a view illustrating a display device 100 including a liquid crystal layer.

Referring to FIG. 12, a display device 100 according to embodiments of the disclosure includes a first substrate 210, a color filter layer 220, a color pattern stack 230, a planarization layer 250, a liquid crystal layer 420, a second substrate 410, and a sensor module 450.

Referring to FIG. 12, the first substrate 210, color filter layer 220, color pattern stack 230, planarization layer 250, and second substrate 410 are identical or similar to those described in connection with FIG. 10, and no detailed description thereof is thus given.

Referring to FIG. 12, the color pattern stack 230 positioned to correspond to the sensor area 170 may be disposed on the first substrate 210. The color pattern stack 230 may be disposed on the same layer as the color filter layer 220.

The color pattern stack 230 may include various embodiments of the color pattern stack 230 described in connection with FIGS. 5 to 11.

Referring to FIG. 12, the liquid crystal layer 420 may be disposed between the planarization layer 250 and the second substrate 410.

Referring to FIG. 12, column spacers 425 and 435 may be provided in the liquid crystal layer 420 as a means to maintain a constant gap between the planarization layer 250 and the second substrate 410, supporting the planarization layer 250 and the second substrate 410.

Referring to FIG. 12, the second substrate 410 may be a TFT substrate including a thin film transistor TFT. The TFT substrate may include various signal lines and a capacitor, as well as the thin film transistor TFT. The thin film transistor TFT may include a switching thin film transistor, a driving thin film transistor, and a sensing thin film transistor. The signal lines may include gate lines, data lines, power lines, and reference lines.

A backlight unit (not shown) serving as a light source may be provided on the rear surface of the second substrate 410, so that light emitted from the backlight unit may pass through the color filter layer 220 to the outside.

Referring to FIG. 12, there may be included a sensor module 450 positioned in an area corresponding to the sensor area 170 and disposed on a rear surface of the second substrate 410. The sensor module 450 includes, but is not limited to, an illuminance sensor, or a thing and human body recognition sensor.

The sensor module 450 may be an infrared (IR) sensor module that uses an infrared wavelength band. The infrared (IR) sensor module may detect the outside of the display device using light in the infrared wavelength band.

Referring to FIG. 12, a transparent resin 430 may be disposed between the color pattern stack 230 and the second substrate 410 in the sensor area 170. When the planarization layer 250 covers the color pattern stack 230, the transparent resin 430 may be disposed between the planarization layer 250 and the second substrate 410.

Meanwhile, the display device 100 according to embodiments of the disclosure may further include a camera area disposed adjacent to the sensor area 170. In the camera area, a transparent resin may be disposed between the first substrate 210 and the second substrate 410. When the planarization layer 250 covers the first substrate 210, the transparent resin may be disposed between the planarization layer 250 and the second substrate 410.

The transparent resin may be disposed not to form an air gap between the color pattern stack 230 of the sensor area 170 and the second substrate 410 or between the first substrate 210 of the camera area and the second substrate 410. If an air gap is present between the color pattern stack 230 of the sensor area 170 and the second substrate 410, the light passing through the color pattern stack 230 may be scattered in the air gap, deteriorating or lowering the efficiency of light incident on the sensor module 450. If an air gap is present between the first substrate 210 and the second substrate 410 of the camera area, the light passing through the first substrate 210 may be scattered in the air gap, deteriorating or lowering the efficiency of light incident on the camera module.

The transparent resin disposed in the sensor area and camera area is described in detail with reference to FIG. 14.

FIG. 13 is a view illustrating a display device 100 including a transparent area.

Referring to FIG. 13, a display device 100 according to embodiments of the disclosure includes a first substrate 210, a color filter layer 220, a color pattern stack 230, a planarization layer 250, a second substrate 310, and a sensor module 350.

Referring to FIG. 13, the first substrate 210, color filter layer 220, color pattern stack 230, planarization layer 250, second substrate 310, and sensor module 350 are identical or similar to those described in connection with FIG. 10, and no detailed description thereof is thus given.

Referring to FIG. 13, the first substrate 210 may include a plurality of subpixels SP, a transparent area TA, and a sensor area 170. The display device 100 shown in FIG. 13 may have the same or substantially same configuration as the display device 100 shown in FIG. 10 except that it further includes a transparent area TA.

Referring to FIG. 13, the color filter layer 220 may further include a transparent area TA in which a color filter is not disposed. A transparent planarization layer 250 may be disposed in the transparent area TA without using a separate color resin. The transparent area may be used as a transmissive area that transmits external light or as a white (W) subpixel that emits white (W) light.

Referring to FIG. 13, as no light emitting element is disposed in the transparent area TA so that there is no light emission by a light emitting element, the transparent area may operate as a transmissive area transmitting external light and be used in a transparent display device.

Meanwhile, when a white light emitting element (not shown) is disposed in the transparent area TA, the transparent area TA may operate as a white W subpixel.

Referring to FIG. 13, the color pattern stack 230 positioned to correspond to the sensor area 170 may be disposed on the first substrate 210. The color pattern stack 230 may be disposed on the same layer as the color filter layer 220.

The color pattern stack 230 may include various embodiments of the color pattern stack 230 described in connection with FIGS. 5 to 11.

Referring to FIG. 13, there may be included a sensor module 350 positioned in an area corresponding to the sensor area 170 and disposed on a rear surface of the second substrate 310. The sensor module 350 includes, but is not limited to, an illuminance sensor, or a thing and human body recognition sensor.

The sensor module 350 may be an infrared (IR) sensor module that uses an infrared wavelength band. The infrared (IR) sensor module may detect the outside of the display device using light in the infrared wavelength band.

Referring to FIG. 13, a transparent resin may be disposed between the color pattern stack 230 and the second substrate 310 in the sensor area 170. When the planarization layer 250 covers the color pattern stack 230, the transparent resin may be disposed between the planarization layer 250 and the second substrate 310.

Meanwhile, the display device 100 according to embodiments of the disclosure may further include a camera area disposed adjacent to the sensor area 170. In the camera area, a transparent resin may be disposed between the first substrate 210 and the second substrate 310. When the planarization layer 250 covers the first substrate 210, the transparent resin may be disposed between the planarization layer 250 and the second substrate 310.

The transparent resin may be disposed not to form an air gap between the color pattern stack 230 of the sensor area 170 and the second substrate 310 or between the first substrate 210 of the camera area and the second substrate 310. If an air gap is present between the color pattern stack 230 of the sensor area 170 and the second substrate 310, the light passing through the color pattern stack 230 may be scattered in the air gap, deteriorating or lowering the efficiency of light incident on the sensor module 350. If an air gap is present between the first substrate 210 and the second substrate 310 of the camera area, the light passing through the first substrate 210 may be scattered in the air gap, deteriorating or lowering the efficiency of light incident on the camera module.

The transparent resin disposed in the sensor area and camera area is described in detail with reference to FIG. 14.

FIG. 14 is a view illustrating a camera area 160 and a sensor area 170 in a display device according to embodiments of the disclosure. For example, FIG. 14 is a cross-sectional view taken along II-II′ of FIG. 1. What is identical or similar to those described in connection with FIGS. 1 to 13 may be omitted or briefly described below.

Referring to FIG. 14, a first transparent resin 525 may be disposed between the first substrate 210 and the second substrate 510 in the camera area 160. When the planarization layer 250 covers the first substrate 210, the first transparent resin 525 may be disposed between the planarization layer 250 and the second substrate 510.

A second transparent resin 520 may be disposed between the color pattern stack 230 and the second substrate 510 in the sensor area 170. When the planarization layer 250 covers the color pattern stack 230, the second transparent resin 520 may be disposed between the planarization layer 250 and the second substrate 510.

The first transparent resin 525 disposed in the camera area 160 may be thicker than the second transparent resin 520 disposed in the sensor area 170.

The first transparent resin 525 may be disposed not to form an air gap between the first substrate 210 and the second substrate 510. If an air gap is present between the first substrate 210 and the second substrate 510, the light passing through the first substrate 210 may be scattered in the air gap, deteriorating or lowering the efficiency of light incident on the camera module 550.

A second transparent resin 520 may be disposed not to form an air gap between the color pattern stack 230 and the second substrate 510. If an air gap is present between the color pattern stack 230 and the second substrate 510, the light passing through the color pattern stack 230 may be scattered in the air gap, deteriorating or lowering the efficiency of light incident on the sensor module 550.

The first transparent resin 525 and the second transparent resin 520 may have substantially the same light transmittance as the first substrate 210 and the second substrate 510. The difference in refractive index between the first transparent resin 525 and the second transparent resin 520 and the first substrate 210 and the second substrate 510 may be about 0.1 or less. For example, the first substrate 210 and the second substrate 510 may have a refractive index of about 1.45 to 1.55, and the first transparent resin 525 and the second transparent resin 520 may have a refractive index of about 1.35 to 1.65.

The first transparent resin 525 and the second transparent resin 520 have high transparency and thus have excellent light transmittance and easy control viscosity, and may be formed of acrylic, urethane, epoxy, vinyl, polyester, or polyamide.

The display device 100 according to embodiments of the disclosure may have the color pattern stack 230 by stacking color patterns having the same or substantially same configuration as the color filter layer 220, thereby implementing an infrared filter selectively transmitting infrared light.

The display device 100 according to embodiments of the disclosure may have the color pattern stack 230 by stacking color patterns having the same or substantially same configuration as the color filter layer 220, thereby implementing an infrared filter that reduces external visibility without having a separate infrared ink.

In the display device 100 according to embodiments of the disclosure, the color pattern stack 230 may be formed by simultaneously stacking color patterns having the same or substantially same configuration as the color filter layer 220, achieving process optimization with a simplified manufacturing process.

In the display device 100 according to embodiments of the disclosure, the color pattern stack 230 may be formed by simultaneously stacking color patterns having the same or substantially same configuration as the color filter layer 220, enabling implementation of a uni-material product.

Embodiments of the disclosure described above are briefly described below.

Embodiments of the disclosure may provide a color filter substrate, comprising a substrate, a color filter layer on the substrate and including a first color filter having a first color, a second color filter having a second color that may be different from the first color, and a third color filter having a first color that may be different from the first color and the second color, and the color filter layer configured to be positioned in areas respectively corresponding to a plurality of subpixels, a color pattern configured to be disposed over a sensor area, the color pattern stack including a first color pattern and a second color pattern on the first color pattern and having a different color from the first color pattern, and a planarization layer on the color filter layer and the color pattern stack.

In the color filter substrate according to embodiments of the disclosure, the first color pattern may have a first thickness and the second color pattern may have a second thickness that may be different from the first thickness.

In the color filter substrate according to embodiments of the disclosure, the color pattern stack may have a thickness in a range of 1 μm to 5 μm.

In the color filter substrate according to embodiments of the disclosure, the color pattern stack may further comprise a third color pattern on at least one of the first color pattern or the second color pattern, the third color pattern having a color different from the first color pattern and the second color pattern.

In the color filter substrate according to embodiments of the disclosure, the first color pattern may have the first color of the first color filter and a same thickness as the first color filter, the second color pattern may have the second color of the second color filter and a same thickness as the second color filter, and the third color pattern may have the third color of the third color filter and a same thickness as the third color filter.

In the color filter substrate according to embodiments of the disclosure, the first thickness of the first color pattern may be thicker than the second thickness of the second color pattern and thicker than a third thickness of the third color pattern.

In the color filter substrate according to embodiments of the disclosure, the first color pattern may be a red color filter, the second color pattern may be a blue color filter, and the third color pattern may be a green color filter.

The color filter substrate according to embodiments of the disclosure may further comprise a transparent area that may lack any color filter.

The color filter substrate according to embodiments of the disclosure may further comprise a black matrix on the substrate, and the black matrix configured to define an opening area exposing each of the plurality of subpixels.

The color filter substrate according to embodiments of the disclosure may further comprise a pattern defining film on the substrate, the pattern defining film defining an area where the color pattern stack is disposed.

Embodiments of the disclosure may provide a display device comprising a first substrate including a plurality of subpixels and a sensor area, a color filter layer including a first color filter having a first color, a second color filter having a second color that is different from the first color, and a third color filter having a third color that is different from the first color and the second color, and the color filter layer overlapping the plurality of subpixels, a color pattern stack overlapping the sensor area, the color pattern stack including a first color pattern and a second color pattern on the first color pattern and having a different color from the first color pattern, a planarization layer on the color filter layer and the color pattern stack, a second substrate on the planarization layer, and a sensor module overlapping the sensor area.

In the display device according to embodiments of the disclosure, the first color pattern may have a first thickness and the second color pattern may have a second thickness that may be different from the first thickness.

In the display device according to embodiments of the disclosure, the color pattern stack may have a thickness in a range of 1 μm to 5 μm.

In the display device according to embodiments of the disclosure, the color pattern stack may further comprise a third color pattern on at least one of the first color pattern or the second color pattern, the third color pattern having a color different from the first color pattern and second color pattern.

In the display device according to embodiments of the disclosure, the first color pattern may have the first color of the first color filter and a same thickness as the first color filter, the second color pattern may have the second color of the second color filter and a same thickness as the second color filter, and the third color pattern may have the third color of the third color filter and a same thickness as the third color filter.

In the display device according to embodiments of the disclosure, the first thickness of the first color pattern may be thicker than the second thickness of the second color pattern and thicker than a third thickness of the third color pattern.

In the display device according to embodiments of the disclosure, the first color pattern may be a red color filter, the second color pattern may be a blue color filter, and the third color pattern may a green color filter.

The display device according to embodiments of the disclosure may further comprise a transparent area that may lack any color filter.

The display device according to embodiments of the disclosure may further comprise a black matrix, and defining an opening area exposing each of the plurality of subpixels.

The display device according to embodiments of the disclosure may further comprise a pattern defining film, and defining an area where the color pattern stack is disposed.

The display device according to embodiments of the disclosure may further comprise a first transparent resin in an area overlapping the sensor area, the first transparent resin between the color pattern stack and the second substrate.

The display device according to embodiments of the disclosure may further comprise a camera area adjacent to the sensor area and a second transparent resin overlapping the camera area, the second transparent resin between the first substrate and the second substrate.

In the display device according to embodiments of the disclosure, the second transparent resin overlapping the camera area may be thicker than the first transparent resin overlapping the sensor area.

The display device according to embodiments of the disclosure may further comprise a light emitting element between the planarization layer and the second substrate and an encapsulation layer on the light emitting element. The light emitting element may include a first electrode on the second substrate, a light emitting layer on the first electrode, and a second electrode on the light emitting layer. The second substrate may be a thin film transistor (TFT) substrate including a thin film transistor.

In the display device according to embodiments of the disclosure, the first electrode may include a reflective electrode and a transparent electrode.

The display device according to embodiments of the disclosure may further comprise a light emitting element between the planarization layer and the second substrate and an encapsulation layer on the light emitting element. The light emitting element may include a first electrode on the planarization layer, a light emitting layer on the first electrode, and a second electrode on the light emitting layer. The first substrate may be a TFT substrate including a thin film transistor.

In the display device according to embodiments of the disclosure, the second electrode may include a reflective electrode and a transparent electrode.

The display device according to embodiments of the disclosure may further comprise a liquid crystal layer disposed between the second substrate and the planarization layer. The second substrate may be a thin film transistor (TFT) substrate including a thin film transistor.

Embodiments of the disclosure may provide a display device comprising a substrate including a first area and a second area that may be spaced apart from the first area, a plurality of subpixels in the first area without being in the second area, a color filter overlapping the plurality of subpixels in the first area, and a color pattern stack overlapping the second area, the color pattern stack including a first color pattern having a first color and a second color pattern on the first color pattern and having a second color that may be different from the first color.

In the display device according to embodiments of the disclosure, the color filter may include a first color filter having a first color, a second color filter having a second color that may be different from the first color, and a third color filter having a third color that may be different from the first color and the second color,
wherein the first color of the first color pattern may be a same as the first color of the first color filter and the second color of the second color pattern may be a same as the second color of the second color filter.

In the display device according to embodiments of the disclosure, the first color pattern may have a first thickness and the second color pattern may have a second thickness that may be different from the first thickness.

In the display device according to embodiments of the disclosure, the color pattern stack may further comprise a third color pattern on at least one of the first color pattern or the second color pattern, the third color pattern having a color different from the first color pattern and the second color pattern.

In the display device according to embodiments of the disclosure, the first color pattern may have a same thickness as the first color filter, the second color pattern may have a same thickness as the second color filter, and the third color pattern may have a same thickness as the third color filter.

In the display device according to embodiments of the disclosure, The display device may further comprise a sensor that may overlap the second area without overlapping the first area.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

What is claimed:

1. A color filter substrate, comprising:
a substrate;
a color filter layer on the substrate and including a first color filter having a first color, a second color filter having a second color that is different from the first color, and a third color filter having a third color that is different from the first color and the second color, and the color filter layer configured to be positioned in areas respectively corresponding to a plurality of subpixels;
a color pattern stack configured to be disposed over a sensor area, the color pattern stack including a first color pattern and a second color pattern on the first color pattern and having a different color from the first color pattern; and
a planarization layer on the color filter layer and the color pattern stack.

2. The color filter substrate of claim 1, wherein the first color pattern has a first thickness and the second color pattern has a second thickness that is different from the first thickness.

3. The color filter substrate of claim 1, wherein the color pattern stack has a thickness in a range of 1 μm to 5 μm.

4. The color filter substrate of claim 2, wherein the color pattern stack further comprises:
a third color pattern on at least one of the first color pattern or the second color pattern, the third color pattern having a color different from the first color pattern and the second color pattern.

5. The color filter substrate of claim 4, wherein the first color pattern has the first color of the first color filter and a same thickness as the first color filter, the second color pattern has the second color of the second color filter and a same thickness as the second color filter, and the third color pattern has the third color of the third color filter and a same thickness as the third color filter.

6. The color filter substrate of claim 5, wherein the first thickness of the first color pattern is thicker than the second thickness of the second color pattern and thicker than a third thickness of the third color pattern.

7. The color filter substrate of claim 5, wherein the first color pattern is a red color filter, the second color pattern is a blue color filter, and the third color pattern is a green color filter.

8. The color filter substrate of claim 1, further comprising:
a transparent area that lacks any color filter.

9. A display device, comprising:
a first substrate including a plurality of subpixels and a sensor area;
a color filter layer including a first color filter having a first color, a second color filter having a second color that is different from the first color, and a third color filter having a third color that is different from the first color and the second color, and the color filter layer overlapping the plurality of subpixels;
a color pattern stack overlapping the sensor area, the color pattern stack including a first color pattern and a second color pattern on the first color pattern and having a different color from the first color pattern;
a planarization layer on the color filter layer and the color pattern stack;
a second substrate on the planarization layer; and
a sensor module overlapping the sensor area.

10. The display device of claim 9, further comprising:
a black matrix defining an opening area exposing each of the plurality of subpixels.

11. The display device of claim 9, further comprising:
a pattern defining film defining an area where the color pattern stack is disposed.

12. The display device of claim 9, further comprising:
a first transparent resin in an area overlapping the sensor area, the first transparent resin between the color pattern stack and the second substrate.

13. The display device of claim 12, further comprising:
a camera area adjacent to the sensor area; and
a second transparent resin overlapping the camera area, the second transparent resin between the first substrate and the second substrate.

14. The display device of claim 13, wherein the second transparent resin overlapping the camera area is thicker than the first transparent resin overlapping the sensor area.

15. A display device comprising:
a substrate including a first area and a second area that is spaced apart from the first area;
a plurality of subpixels in the first area without being in the second area;
a color filter overlapping the plurality of subpixels in the first area; and
a color pattern stack overlapping the second area, the color pattern stack including a first color pattern having a first color and a second color pattern on the first color pattern and having a second color that is different from the first color.

16. The display device of claim 15, wherein the color filter includes a first color filter having a first color, a second color filter having a second color that is different from the first color, and a third color filter having a third color that is different from the first color and the second color,
wherein the first color of the first color pattern is a same as the first color of the first color filter and the second color of the second color pattern is a same as the second color of the second color filter.

17. The display device of claim 16, wherein the first color pattern has a first thickness and the second color pattern has a second thickness that is different from the first thickness.

18. The display device of claim 17, wherein the color pattern stack further comprises:
a third color pattern on at least one of the first color pattern or the second color pattern, the third color pattern having a color different from the first color pattern and the second color pattern.

19. The display device of claim 18, wherein the first color pattern has a same thickness as the first color filter, the second color pattern has a same thickness as the second color filter, and the third color pattern has a same thickness as the third color filter.

20. The display device of claim 15, further comprising:
a sensor that overlaps the second area without overlapping the first area.
